(19) United States
(12) Patent Application Publication
(10) Pub. No.: US 2003/0008495 A1
(43) Pub. Date: Jan. 9, 2003

(54) Selective barrier metal fabricated for interconnect structure manufacturing process

(76) Inventors: Chen-Chiu Hsue, Hsinchu (TW); Shyh-Dar Lee, Hsinchu Hsien (TW); Lung Chen, Hsinchu (TW); Ching-Fan Wang, Hsinchu (TW)

Correspondence Address: BIRCH STEWART KOLASCH & BIRCH, PO BOX 747, FALLS CHURCH, VA, 22040-0747, US

(21) Appl. No.: 09/897,134

(22) Filed: Jul. 3, 2001

(51) Int. Cl. H01L 21/4763

(52) U.S. Cl. 438/627; 438/634; 438/638; 438/643

(57) ABSTRACT

A method to fabricate an interconnect structure is provided. First, an inter-metal dielectric layer is formed on a substrate. Then the inter-metal dielectric layer is etched to form a trench, and a barrier layer is formed on the trench. After, a metal layer is formed to fill in the trench over the barrier layer. Then a chemical mechanical polishing (CMP) process is performed to remove the barrier layer and the metal layer on the inter-metal dielectric layer. Finally, a conductive sealing layer is formed to cover the metal layer.

### BACKGROUND OF THE INVENTION

1. Field of the Invention

The present invention relates in general to a process for manufacturing an interconnect structure. In particular, the present invention relates to forming a conductive sealing layer having good metal adhesion characteristics to cover a metal layer. Therefore, the adhesion between the sealing layer and the metal layer of the interconnect structure will be improved to avoid the problems of electro-migration.

2. Description of the Related Art

In ultra large-scale integrated (ULSI) circuit manufacturing, semiconductor devices are fabricated on a substrate or a silicon wafer. After the formation of the devices, metal lines for interconnection are defined using a metallization process. As the integration of integrated circuits increases, manufacturing with high yield and highly reliable metal interconnect lines is hard to achieve. A method of fabricating a metal-damascene structure is to etch trenches for metal interconnect lines and then fill the trenches with metal material. In addition, chemical mechanical polishing (“CMP” hereinafter) is used to polish the metal material. The method offers a better way to fabricate a submicron VLSI interconnection with high performance and high reliability.

In the following description, a conventional method for fabricating a damascene structure on a substrate is explained with reference to FIGS. 1A to 1D.

First, referring to FIG. 1A, a substrate 100 is provided and a metal interconnect line 110 is fabricated in the substrate 100. Next, a sealing layer 120 is formed covering the metal interconnect line 110. Then, an inter-metal dielectric (IMD) layer 120 is formed covering the sealing layer 120. The material of the sealing layer 120 can be silicon nitride (SiN) or silicon carbide (SiC). The sealing layer 120 is provided for sealing the metal interconnect line 110 and for avoiding the ions of the metal interconnect line 110 diffusing to other parts of the semiconductor device, causing a short circuit of the semiconductor device. Next, referring to FIG. 1B, the IMD layer 130 is defined by the damascene process to form a dual damascene structure 140 extending through the IMD layer 130 and the sealing layer 120 to the metal interconnect line 110.

Then, referring to FIG. 1C, a barrier layer 150 is formed on the sidewalls and the bottom of the dual damascene structure 140 and the IMD layer 130 by CVD or PVD. Afterwards, a metal layer 160 is formed on the dual damascene structure 140 on the barrier layer 150. Finally, referring to FIG. 1D, CMP is performed to remove the metal layer 160 and the barrier layer 150 on the IMD layer 130 outside the dual damascene structure 140.

In the prior art, a dielectric layer of silicon nitride or silicon carbide is used as a sealing layer to avoid copper ion diffusing to the IMD layer. However, adhesion is poor between the metal layer and the sealing layer. Hence, electro-migration problems with the metal layer are created, degrading the reliability of the semiconductor device.

Moreover, while CMP is performed, some metal oxide will be generated on the surface of the metal line 160. For example, if the metal is copper, the copper oxidizes, producing copper oxide (Cu₂O). The oxide will increase the resistance of the metal line and cause the surface of the metal layer to bulge. Thus, adhesion between the sealing layer and the metal line will be decreased. Furthermore, the increased resistance of the metal line will generate more heat during operation of the semiconductor device. Moreover, when the adhesion between the sealing layer and the metal line deteriorates, the electro-migration of the metal line will be degraded, which will negatively influence the performance of the semiconductor device.

### SUMMARY OF THE INVENTION

The object of the present invention is to provide a method for interconnect structure manufacturing, which can improve adhesion between the metal layer and the sealing layer. According to the present invention, a conductive sealing layer is formed covering the metal layer, wherein the material of the conductive sealing layer may be titanium (Ti), titanium nitride (TiN), tantalum (Ta), or tantalum nitride (TaN). While a sealing layer containing such material is formed on the metal layer, the metal layer and the sealing layer will react, generating the product on the interface of the sealing layer and the metal layer, improving the adhesion between the metal layer and the sealing layer.

To achieve the above-mentioned object, the present invention provides a method to fabricate an interconnect structure, comprising the following steps.

First, an inter-metal dielectric layer is formed on a substrate. Then the inter-metal dielectric layer is etched to form a trench. A barrier layer is formed on the trench. Afterwards, a metal layer is formed to fill the trench over the barrier layer. Then CMP is performed to remove the barrier layer and the metal layer on the inter-metal dielectric layer. After CMP, a conductive sealing layer is formed on the metal layer. Finally, a sealing layer is formed to cover the adhesion layer.

### BRIEF DESCRIPTION OF THE DRAWINGS

The present invention will become more fully understood from the detailed description given hereinbelow and the accompanying drawings, given by way of illustration only and thus not intended to be limitative of the present invention.

FIGS. 1A-1D are section views illustrating a conventional method of manufacturing an interconnect structure.

FIGS. 2A-2J are section views illustrating a method of manufacturing an interconnect structure according to the embodiment of the present invention.

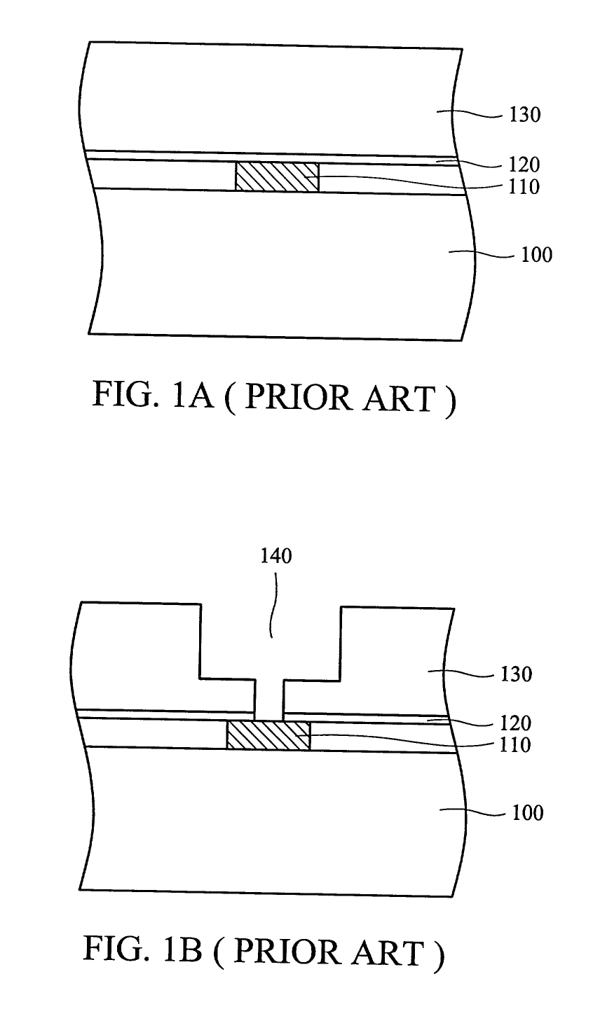

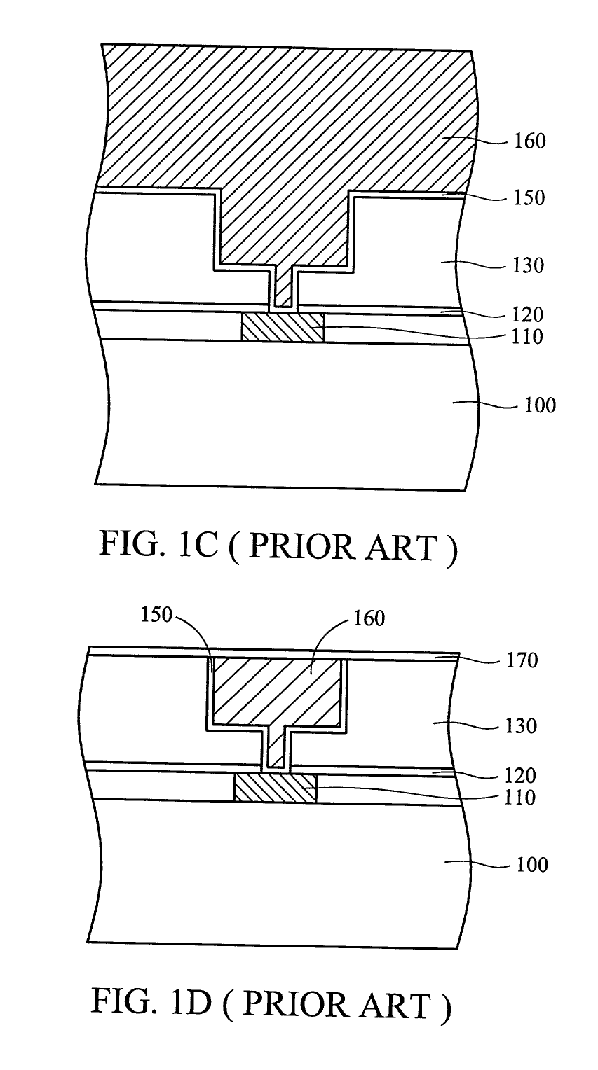

### DETAILED DESCRIPTION OF THE PREFERRED EMBODIMENT

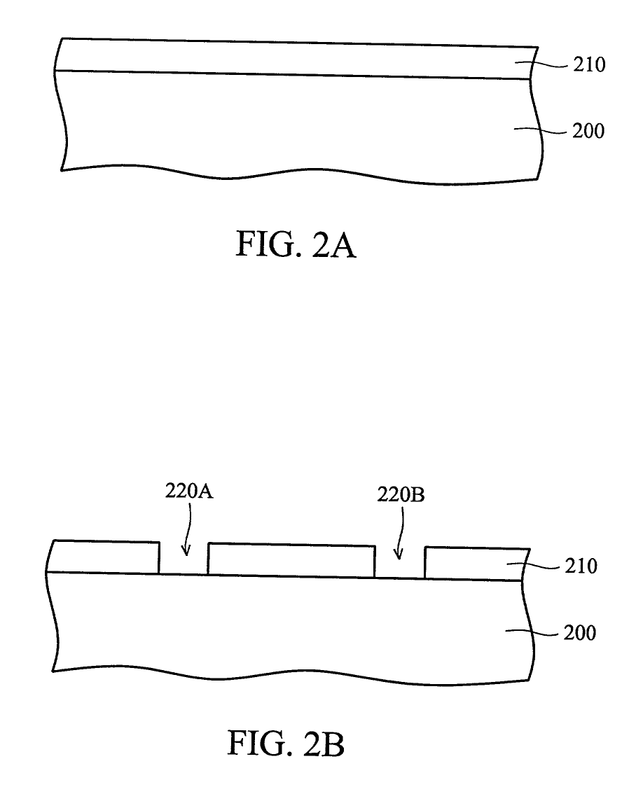

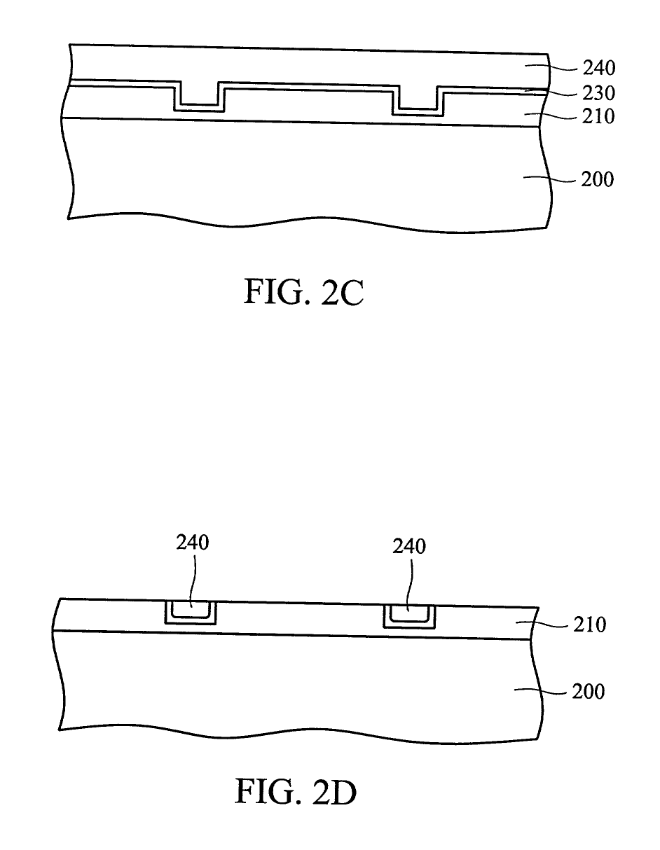

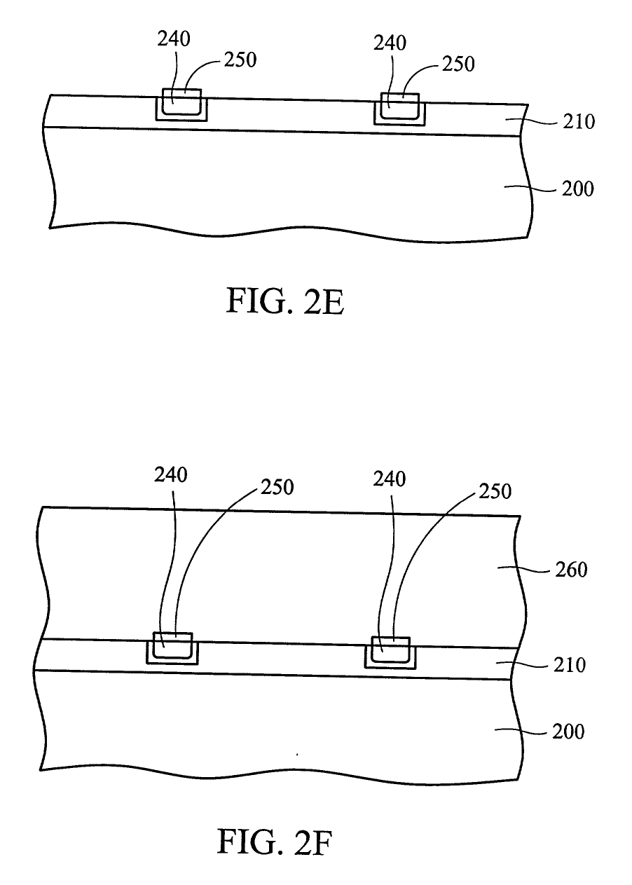

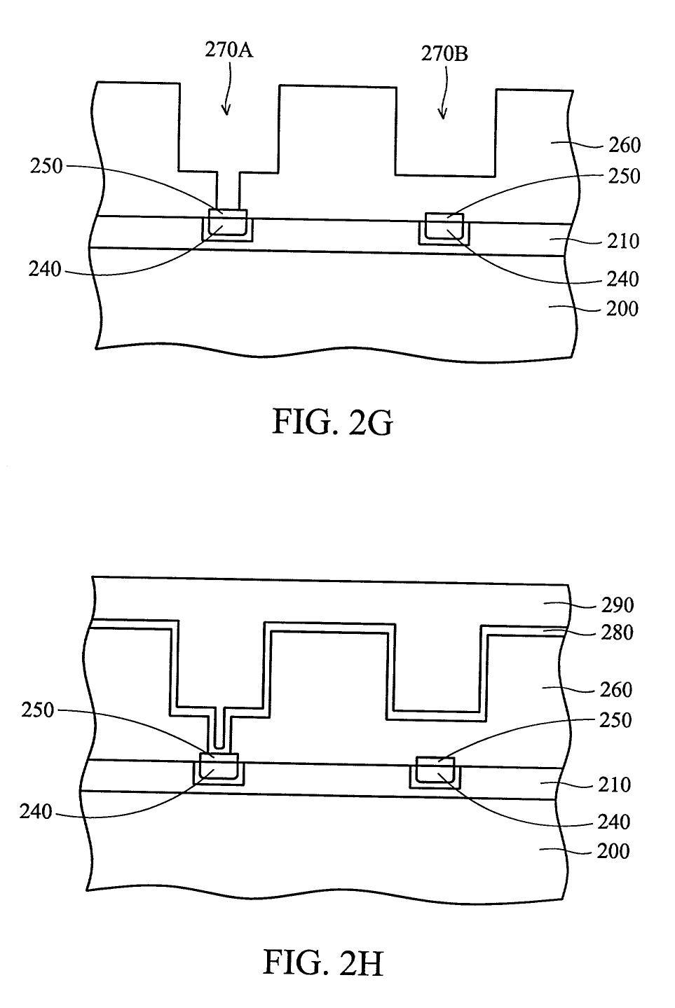

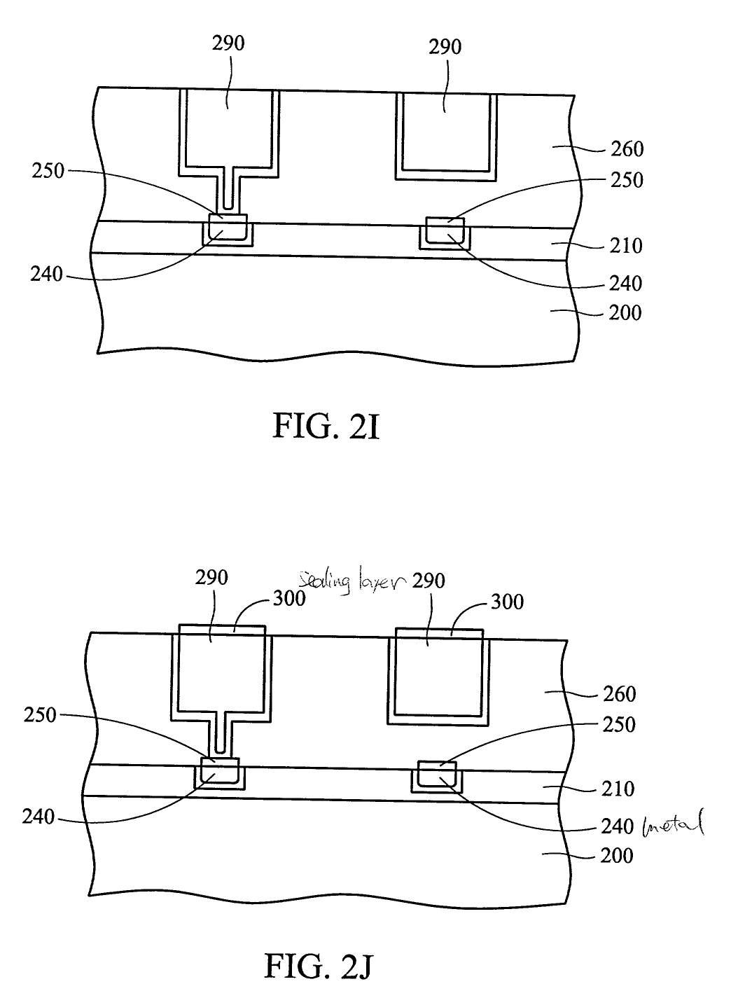

A method of fabricating a dual damascene structure on a substrate is described herein with reference to FIGS. 2A to 2J.

First, referring to FIG. 2A, a substrate 200 is provided for the present embodiment. Then, an inter-metal dielectric (IMD) layer 210 is formed on the substrate. The inter-metal dielectric layer 210 is composed of single layer or multi-layer low k dielectric material, wherein the k is dielectric constant. Next, referring to FIG. 2B, the inter-metal dielectric layer 210 is etched by lithography to form the trenches 220A and 220B. In the present embodiment, the trenches 220A and 220B are formed by anisotropically etching, and the depths of the trenches 220A and 220B are between about 2000 to 6000 angstroms.

Referring to FIG. 2C, a barrier layer 230 is formed on the sidewalls and the bottom of the trenches 220A and 220B. Then the metal layer 240 is disposed on the trench 220A and 220B on the barrier layer 230. The material of the metal layer 240 may be copper, aluminum, tungsten, or others. In this embodiment, the metal layer 240 is a copper layer.

Referring to FIG. 2D, CMP is performed to remove the metal layer 240 and the barrier layer 230 from the inter-metal dielectric layer 210. However, during the CMP process and after, the copper oxide (Cu₂O) is generated on the remained metal layer 240 in the trenches 220A and 220B because of wetness. Moreover, the copper oxide (Cu₂O) will cause the surface of the metal layer to bulge. Therefore, the adhesion between the sealing layer 260, which is formed later, and the metal layer 240 is deteriorated. Hence, the reliability of the semiconductor is decreased.

A reduction process is performed to solve this problem. The reduction process provides a reduction gas to the surface of the metal layer 240. Therefore, the Cu₂O is reduced to Cu by free radicals. In the present invention, the reduction gas may be ammonia (NH₃), hydrogen (H₂), or silane (SiH₄). Alternately, the reduction gas may be a mixture of ammonia (NH3) and hydrogen (H2), or a mixture of silane (SiH4) and hydrogen (H2). Preferably, the silane is used as the reduction gas. The reduction process is under the following conditions: flow rate of the reduction process is between about 20 to 400 sccm; the pressure of the reduction process is between about 0.01 to 10 torr; and the temperature of the reduction process is between about 180 to 620° C. Therefore, the metal oxide is removed and the surface of the metal layer is planaried.

Afterwards, referring to FIG. 2E, a conductive sealing layer 250 is formed covering on each metal layer 240. The material of the conductive sealing layer 250 may be titanium (Ti), titanium nitride (TiN), tantalum (Ta), or tantalum nitride (TaN), and the thickness of the sealing layer 250 is between about 20 to 150 angstroms. In addition, the technology for forming the conductive sealing layer may comprise the electroplating process, some specific chemical reaction, and silicide reaction, etc.

In the present invention, the reliability of the semiconductor device is improved by the conductive sealing layer 250, since the interface of the conductive sealing layer 250 and the metal layer 240 causes reaction and generates products, such as copper titanium alloy (CuTi), copper tantalum alloy (CuTa), copper titanium nitride (CuTiN), or copper tantalum nitride (CuTiN), etc, which adhere the conductive sealing layer 250 and the metal layer 240 to each other. Therefore, the adhesion between the sealing layer 250 and the metal layer 240 is improved. Moreover, the sealing layer 250 is effective to avoid the copper ions diffusing to the inter-metal dielectric layer 260, which is formed in the following steps.

Referring to FIG. 2F, an inter-metal dielectric layer 260 is formed on the conductive sealing layer 250, wherein the inter-metal dielectric layer 260 is composed of single layer or multi-layer low k dielectric materials.

Next, referring to the FIG. 2G, the IMD layer 260 is defined by the damascene process to form a trench 270B and a dual damascene structure 270A extending through the IMD layer 260 to the conductive sealing layer 250.

Then, referring to FIG. 2H, a barrier layer 280 is formed on the IMD layer 260 and the sidewalls and the bottom of the dual damascene structure 270A and the trench 270B by CVD or PVD. Afterwards, a metal layer 290 is formed on the dual damascene structure 270A and the trench 270B on the barrier layer 280. The material of the metal layer 290 may be copper, aluminum, or tungsten, etc. In this present embodiment, the metal layer 290 is a copper layer.

Afterwards, referring to FIG. 2I, after the metal layer 290 is formed, CMP is performed to remove the metal layer 290 and the barrier layer 280 on the IMD layer 260. As mentioned above, during CMP and after, copper oxide (Cu₂O) is generated on the remaining metal layer 290.

Thus, a reduction process is performed. The reduction process provides a reduction gas to the surface of the metal layer 290. Therefore, the Cu₂O is reduced to Cu by free radicals. In the present invention, the reduction gas may be ammonia (NH₃), hydrogen (H₂), or silane (SiH₄). Alternately, the reduction gas may be a mixture of ammonia (NH3) or hydrogen (H₂), or a mixture of silane (SiH₄) and hydrogen (H₂). Preferably, the reduction gas is silane (SiH₄). The reduction process is under the following conditions: flow rate of the reduction process is between about 20 to 400 sccm; the pressure of the reduction process is between about 0.01 to 10 torr; and the temperature of the reduction process is between about 180 to 620° C.

Finally, referring to FIG. 2J, a conductive sealing layer 300 is formed covering the metal layer 290 in dual damascene structure 270A and the trench 270B, respectively. The material of the conductive sealing layer 250 may be titanium (Ti), titanium nitride (TiN), tantalum (Ta), or tantalum nitride (TaN), and the thickness of the sealing layer 250 is between about 20 to 150 angstroms. In addition, the technology for forming the conductive sealing layer may comprise the electroplating process, some specific chemical reaction, and silicide reaction, etc.

As the advantages mentioned above, the reliability of the semiconductor device is improved by the conductive sealing layer 300, since the interface of the conductive sealing layer 300 and the metal layer 290 causes the reaction and generates products, such as copper titanium alloy (CuTi), copper tantalum alloy (CuTa), copper titanium nitride (CuTiN), or copper tantalum nitride (CuTiN), etc, which adhere the conductive sealing layer 300 and the metal layer 290 to each other. Therefore, adhesion between the sealing layer 300 and the metal layer 290 is improved.

Moreover, while the metal layer 290 in the dual damascene structure 270A connects with the metal layer 240, it is unnecessary to remove the sealing layer 250. It is because the sealing layer is conductible. Therefore, the elasticity of queue time of the interconnect structure fabricating process is improved.

According to the method of the present invention, the adhesion between the sealing layer and the metal layer is improved. Therefore, the present invention improves the electro-migration of copper and the adhesion between the sealing layer and the metal layer. Thus, the reliability of the semiconductor device is improved effectively.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A method to fabricate an interconnect structure, comprising the following steps:
providing a substrate;
forming an inter-metal dielectric layer on the substrate;
forming a trench on the inter-metal dielectric layer by etching the inter-metal dielectric layer;
forming a barrier layer on the inter-metal dielectric layer and sidewalls and a bottom of the trench;
forming a metal layer on the barrier layer to fill into the trench;
performing a chemical mechanical polishing process to planarize a surface of the metal layer;
forming a conductive sealing layer to cover the surface of the metal layer.

2. The method as claimed in claim 1, further comprising the following step:
performing a reduction process by providing a reduction gas to remove the metal oxide generated on the metal layer after the chemical mechanical polishing process is performed.

3. The method as claimed in claim 2, wherein the material of the conductive sealing layer is selected from the group consisting of titanium (Ti), titanium nitride (TiN), tantalum (Ta), or tantalum nitride (TaN).

4. The method as claimed in claim 3, wherein the thickness of the conductive sealing layer is between about 20 to 150 angstroms.

5. The method as claimed in claim 4, wherein the material of the metal layer is copper.

6. The method as claimed in claim 5, wherein the reduction gas is silane (SiH₄).

7. The method as claimed in claim 5, wherein the reduction gas is selected from the group consisting of ammonia (NH3), hydrogen (H₂), and silane (SiH₄).

8. A method to fabricate an interconnect structure, comprising the following steps:
providing a substrate having a metal line thereon;
forming a first conductive sealing layer to cover the metal line;
forming an inter-metal dielectric layer on the first conductive sealing layer and the substrate;
defining the inter-metal dielectric layer by a damascene process to form a damascene structure extending through the inter-metal dielectric layer to the first sealing layer;
forming a barrier layer on the inter-metal dielectric layer and sidewalls and a bottom of the damascene structure;
forming a metal layer on the barrier layer to fill into the damascene structure;
performing a chemical mechanical polishing process to planarize a surface of the damascene structure;
performing a reduction process by providing a reduction gas to remove the metal oxide generated on the metal layer; and
forming a second conductive sealing layer to cover the metal layer.

9. The method as claimed in claim 8, wherein the material of the first and second conductive sealing layer is selected from the group consisting of titanium (Ti), titanium nitride (TiN), tantalum (Ta), or tantalum nitride (TaN).

10. The method as claimed in claim 9, wherein the thickness of the first and second conductive sealing layer is between about 20 to 150 angstroms.

11. The method as claimed in claim 10, wherein the material of the metal layer is copper.

12. The method as claimed in claim 11, wherein the reduction gas is silane (SiH₄).

13. The method as claimed in claim 11, wherein the reduction gas is selected from the group consisting of ammonia (NH3), hydrogen (H₂), and silane (SiH₄).
